(19) United States
(12) Patent Application Publication
(10) Pub. No.: US 2004/0119163 A1
(43) Pub. Date: Jun. 24, 2004

(54) Method of making semiconductor devices using carbon nitride, a low-dielectric-constant hard mask and/or etch stop

(76) Inventors: Lawrence Wong, Beaverton, OR (US); Jihperng Leu, Portland, OR (US); Grant Kloster, Hillsboro, OR (US); Andrew W. Ott, Hillsboro, OR (US); Patrick Morrow, Portland, OR (US)

Correspondence Address: Edwin H. Taylor, BLAKELY, SOKOLOFF, TAYLOR & ZAFMAN LLP, Seventh Floor, 12400 Wilshire Boulevard, Los Angeles, CA, 90025-1026, US

(21) Appl. No.: 10/328,806

(22) Filed: Dec. 23, 2002

(51) Int. Cl. H01L 23/48

(52) U.S. Cl. 257/758

(57) ABSTRACT

A method for making a semiconductor device using carbon nitride as an etch stop diffusion barrier and/or a hard mask is described. An interconnect structure is made by at least: forming an etch stop diffusion layer, depositing an interlayer dielectric, etching necessary vias and trenches, forming a barrier layer, forming copper alloy, and planarizing. The use of a hard mask in the method is optional. The etch stop diffusion layer, the optional hard mask, or both comprised by carbon nitride.

### BACKGROUND OF THE INVENTION

1. Field of the Invention

The invention generally relates to the field of fabricating semiconductor devices. More specifically, it relates to the materials used for etchant stops and/or hard masks in interconnect structures.

2. Prior Art

Modem integrated circuits generally contain several layers of interconnect structures fabricated above a substrate. The substrate may have active devices and/or conductors that are connected by the interconnect structure.

Current interconnect structures, typically comprising trenches and vias, are usually fabricated in, or on, an interlayer dielectric (ILD). It is generally accepted that, the dielectric material in each ILD should have a low dielectric constant (k) to obtain low capacitance between conductors. Decreasing this capacitance between conductors, by using a low dielectric constant (k), results in several advantages. For instance, it provides reduced RC delay, reduced power dissipation, and reduced cross-talk between the metal lines. For some cases, interconnect structures use dielectric materials such as silicon dioxide (SiO₂) or silicon oxyfluoride (SiOF), which have dielectric constants of approximately 4 and 3.5, respectively. Articles discussing low k dielectrics are: “From tribological coatings to low-k dielectrics for ULSI interconnects,” by A. Grill, Thin Solid Films 398-399 (2001) pages 527-532; “Integration Feasibility of Porous SiLK Semiconductor Dielectric,” by J. J. Waterloos, et al., IEEE Conference Proceedings, IITC, (June 2001) pages 253-354; and “Low-k Dielectrics Characterization for Damascene Integration, “by Simon Lin, et al., IEEE Conference Proceedings, IITC, (June 2001) pages 146-148.

However, these low k dielectrics tend to be extremely porous. The porous nature of low k dielectrics allows copper formed in the trenches and vias, without a barrier, to diffuse into the substrate and/or the dielectric material causing the circuit not to function. Interconnect structures employ an etch stop/diffusion barrier 120 on the upper surface of an interlayer dielectric, as shown in FIG. 1, to eliminate copper diffusion into the underlying layer. Furthermore, an etch stop/diffusion barrier is desirable to stop chemical enchants from etching into the underlying layer. Typically, a material such as silicon nitride (Si₃N₄) or silicon carbide (SiC) is used for the etch stop/diffusion barrier. Nevertheless, these materials have relatively high dielectric constants, which further increase capacitance and RC delay. For example, Si₃N₄ has a dielectric constant in the range of 6.5-10.

Low k dielectrics inherently are mechanically weak. This mechanical weakness is problematic in that, the low k dielectric materials may not adequately support the interconnect structure during fabrication. For example, after forming a copper alloy, a structure is typically planarized using either chemical-mechanical polish (CMP) or electropolishing. Unfortunately, the mechanical weakness of low k dielectric material is not particularly suitable for the stresses associated with the CMP or electropolishing. Therefore, present techniques include the use of a hard mask in the formation of the vias and trenches to increase mechanical strength during fabrication. For instance, silicon nitride (Si₃N₄) or silicon dioxide (SiO₂) is used to form hard masks. Yet, SiN and SiO₂ have approximately a dielectric constant of 6-10 and 4-5, respectively, which further increases capacitance and RC delay.

### BRIEF DESCRIPTION OF DRAWINGS

The embodiments of the present invention are illustrated by way of example and not in the figures of the accompanying drawings, in which references indicate similar elements and in which:

FIG. 1 is a prior art cross-sectional elevation view of an etch stop/diffusion barrier, entirely comprised of either silicon nitride or silicon carbide, formed on the upper surface of an interlayer dielectric.

FIG. 2 is a cross-sectional elevation view of an etch stop/diffusion barrier formed on the upper surface of an underlying layer.

FIG. 3 illustrates the structure of FIG. 2 after an interlayer dielectric is deposited on the etch stop/diffusion barrier.

FIG. 4a illustrates the structure of FIG. 3 after a via, a trench, and etchstop are patterned in the interlayer dielectric.

FIG. 4b illustrates the structure of FIG. 3 after using a hard mask in the formation of the via and the trench.

FIG. 5 illustrates the structure of FIG. 4a after a barrier layer is formed over the dielectric, so as to line the via and the trench.

FIG. 6 illustrates the structure of FIG. 5 after copper alloy is formed over the barrier layer, so as to fill the via and the trench.

FIG. 7a illustrates the structure of FIG. 6 after the copper alloy is planarized.

FIG. 7b illustrates the structure of FIG. 4b, after a barrier layer is formed over the dielectric layer, a copper alloy layer is formed over the barrier layer, and the copper alloy layer is planarized leaving the hard mask.

FIG. 8 illustrates the structure of FIG. 7b, repeated for a multilayered structure.

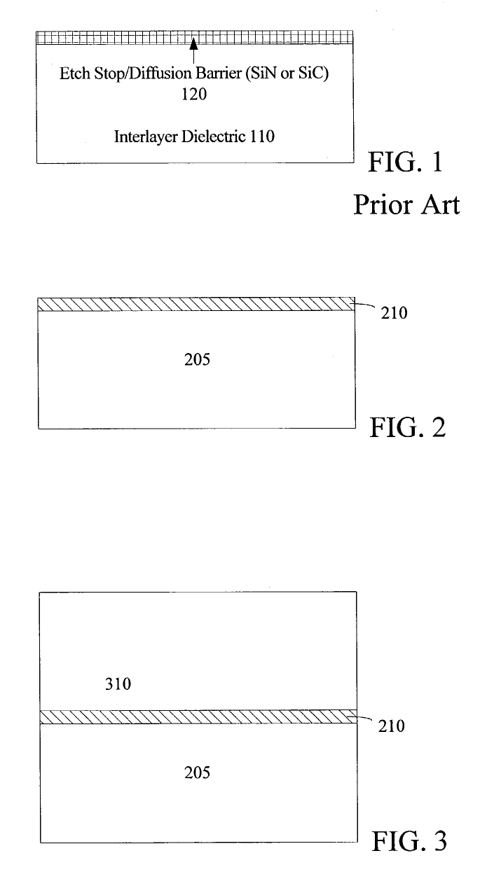

### DETAILED DESCRIPTION

A method for forming an interconnect structure using amorphous carbon nitride (a-C:Nₓ, a-C:N:H, or a-CNₓO_{y}) as an etch stop/diffusion barrier and/or a hard mask is described. In the following description, numerous specific details are set forth, such as specific materials and thicknesses in order to provide a thorough understanding of the present invention. It will be apparent to one skilled in the art that the present invention may be practiced without these specific details. In other instances, well-known processing steps, such as masking and etching steps, have not been described in detail in order to avoid unnecessarily obscuring the present invention.

Referring first to FIG. 2, an underlying layer 205 is illustrated, which often is comprised of several active devices and/or a layer with metal exposed. Underlying layer 205 may be a semiconductor wafer including device regions, other structures such as gates, local interconnects, metal layers, or other active or passive device structures or layers.

An etch stop/diffusion barrier 210 is also illustrated in FIG. 2, which in one embodiment of the present invention is comprised of amorphous carbon nitride (a-C:Nₓ, a-C:N:H, or a-CNₓO_{y}). These materials have a dielectric constant of approximately 1.83.6. In another embodiment, etch stop/diffusion barrier 210 is comprised of silicon nitride (Si₃N₄) or silicon carbide (SiC).

To obtain amorphous carbon nitride, a carbon source, methane (CH₄) or propane (C₃H₈), may be combined with a nitrogen source, nitrogen gas (N₂), nitrogen triflouride (NF₃), ammonia (NH₃), or nitrous oxide (N₂O). Different ratios of nitrogen (10%-90%) and carbon may be prepared with a dilution carrier for preparation of amorphous carbon nitride. In one illustrative example, amorphous carbon nitride could be 10% carbon, 30% nitrogen, and 60% carrier. The composition and phase of amorphous carbon nitride may be tailored to enhance certain properties that may be more desirable for different applications. For example, it may be desirable to alter the composition and phase of the amorphous carbon nitride to increase its hardness, therefore, its mechanical strength when using it for an etch stop/diffusion barrier or a hard mask. As an alternative example, it may be desirable to alter the phase and composition of the amorphous carbon nitride when using it during etch and seal activity or as a dielectric.

The amorphous carbon nitride may be directly deposited by chemical vapor deposition (CVD), plasma enhanced chemical vapor deposition (PECVD), post deposition process of a-C:H films with N₂, H₂/N₂ or NH₃ anneal or plasma, or other methods of reactive radio frequency magnetron sputtering. As an illustrative example, PECVD may be used to form amorphous carbon nitride under the following range of conditions: a temperature of 350 to 450 degrees Celsius; a pressure of 100 millitorr to 2 torr; and a radio frequency power of 100 watts to 2 kilowatts. Articles discussing methods of preparation and dielectric properties of amorphous carbon nitride are: “Amorphous Carbon Nitride Films as a Candidate for Low Dielectric Constant Materials,” by M. Aono, S. Nitta, T. Iwasaki, H. Yokoi, T. Itoh, and S. Nonomura, Mat. Res. Soc. Symp. Proc. Vol 565 (1999) pages 291-296; “Dielectric Properties of Amorphous Carbon Nitride Films,” by M. Aono, T. Katsuno, S. Nitta, T. Itoh, and S. Nonomura, Mat. Res. Soc. Symp. Proc. Vol 593 (2000) pages 493-498.

As shown in FIG. 3, an interlayer dielectric (ILD), such as ILD 310, is deposited on the etch stop/diffusion barrier 210. ILD 310 may be formed from any one of a plurality of known dielectric materials. In one embodiment of the present invention, ILD 310 is formed from a low k dielectric such as a polymer-based dielectric. In another embodiment, a non-organic material such as a carbon-doped oxide is used.

One category of low k materials, the organic polymers, are typically spun-on. A discussion of perfluorocyclobutane (PFCB) organic polymers is found in, “Integration of Perfluorocyclobutane (PFCB).” By C. B. Case, C. J. Case, A. Komblit, M. E. Mills, D. Castillo, R. Liu, Conference Proceedings, ULSI XII.CPOYRGT. 1997, Materials Research Society, beginning at page 449. These polymers are available from companies such as Dupont, Allied Signal, Dow Chemical, Dow Corning, and others.

Another category of low k materials that may be used in the present invention are silica-based such as the nanoporous silica aerogel and xerogel. These dielectrics are discussed in “Nanoporous Silica for Dielectric Constant Less than 2,” by Ramos, Roderick, Maskara and Smith, Conference Proceedings ULSI XII.COPYRGT. 1997, Materials Research Society, beginning at page 455 and “Porous Xerogel Films as UltraLow Permittivity Dielectrics for ULSI Interconnect Applications,” by Jin, List, Lee, Lee, Luttmer and Havermann, Conference Proceedings ULSI XII.COPYRGT. 1997, Materials Research Society, beginning at page 463.

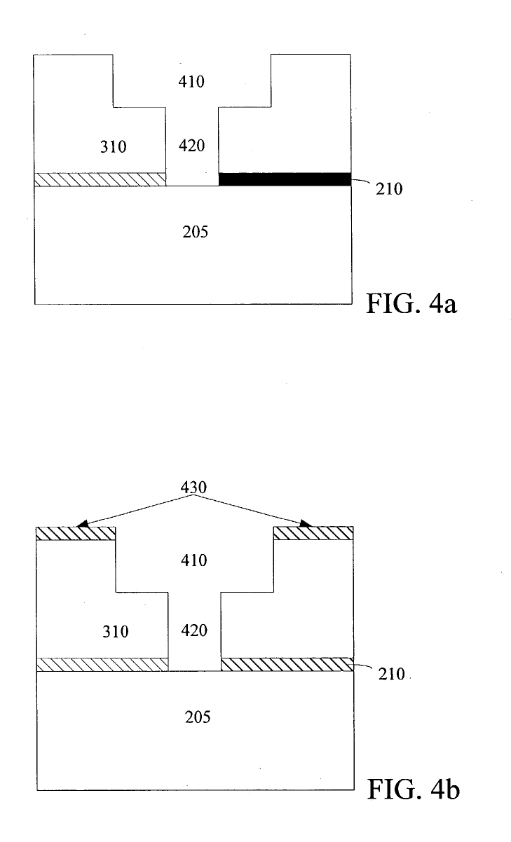

Next vias and trenches, such as via 420 and trench 410 in FIG. 4a, are etched into ILD 310 and through etch stop/diffusion barrier 210. In one embodiment of the present invention, ordinary masking and etching processing is used to form the trench 410, via 420, and any other trenches or vias needed within ILD 310. In another embodiment, in addition to normal masking and etching processes, an optional hard mask 430, as shown in FIG. 4b, may be formed on the dielectric to provide mechanical stability. In one embodiment, optional hard mask 430 is comprised of amorphous carbon nitride. The amorphous carbon nitride used for the optional hard mask 430 may be prepared and formed in the same manner as discussed above for the etch stop/diffusion barrier. In another embodiment, optional hard mask 430 may be made of silicon nitride (Si₃N₄) or silicon dioxide (SiO₂). Yet, in another embodiment optional hard mask 430 can be a dual layer hard mask including a first layer of Si₃N₄ and a second layer of SiO₂. Typically, optional hard mask 430 has a thickness sufficient to withstand process steps such as chemical-mechanical polish or electroplating. As an illustrative example, optional hard mask 430 may have a thickness of 200-4000 Å.

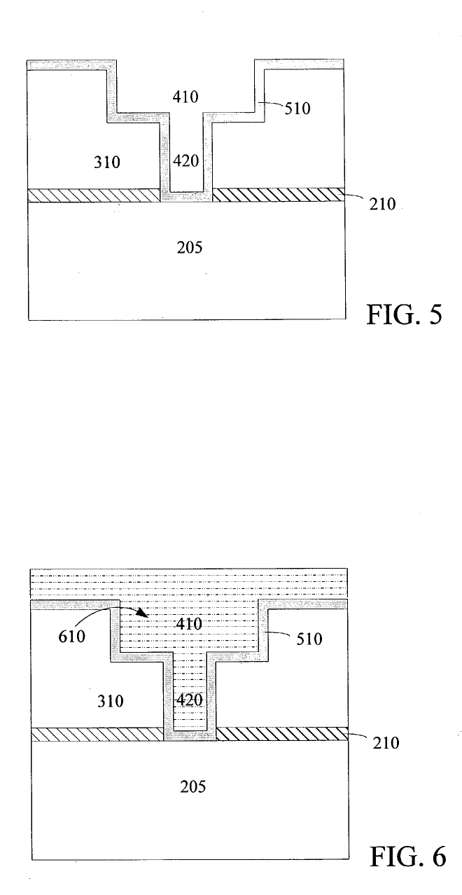

As shown in FIG. 5, a blanket barrier layer 510 is formed on the dielectric layer 310, so as to line the trench 410 and via 420. In an alternative embodiment, where the optional hard mask 430, depicted in FIG. 4b, is used, the blanket barrier layer is formed on the optional hard mask 430, as well as in the via 420 and trench 410 so as to line them. The barrier layer 510 is used to prevent copper from diffusing into the dielectric material, as is well known. For this purpose, approximately 200 Å of tantalum or tantalum nitride may be used for barrier layer 510.

Next, a conventional plating process is used to form the copper or copper alloy layer 610 as shown in FIG. 6.

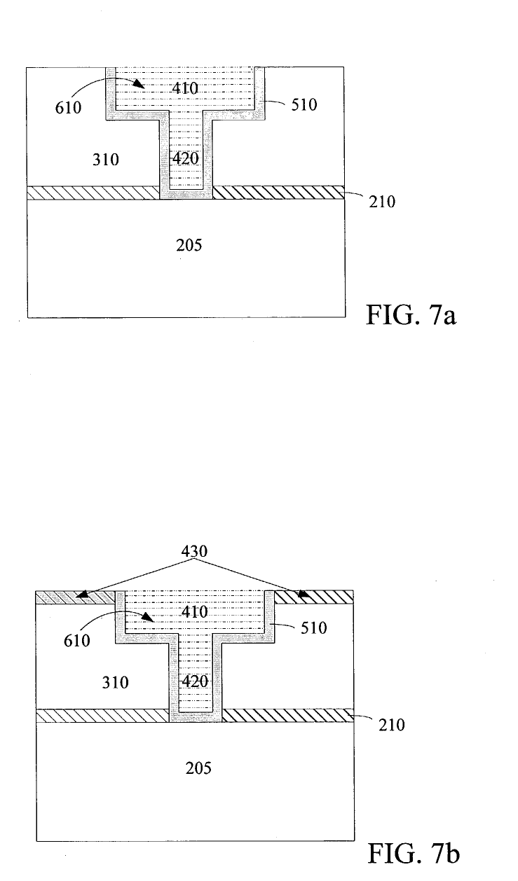

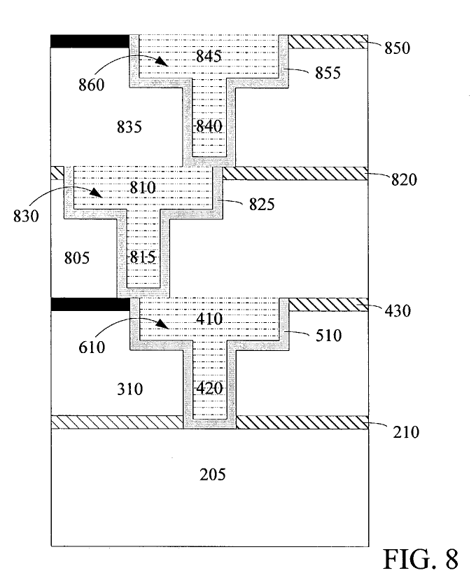

As shown in FIG. 7a, the structure of FIG. 6 is now planarized, removing copper alloy layer 610 and barrier layer 510 from the upper surface of the dielectric. In another embodiment of the present invention, where optional hard mask 430 is used, the copper can be planarized removing the copper alloy layer 610, the barrier layer 510, and the optional hard mask 430 from the upper surface of the dielectric. In an alternative embodiment, where optional hard mask 430 is used, the copper can be planarized removing the copper alloy layer 610 and the barrier layer 510 from the upper surface of the dielectric, but leaving the optional hard mask 430 as shown in FIG. 7b. Hard mask 430 may then be used as an etch stop/diffusion barrier for upper layers, as shown in FIG. 8.

As an illustrative example, planarizing can be done by either chemical-mechanical polish (CMP) or electropolishing. Both CMP and electropolishing techniques for planarizing are well known. Electropolishing and related technology is described in U.S. Pat. Nos. 5,096,550; 6,017,437; 6,143,155; and 6,328,872.

Furthermore, these methods described above may be repeated to create multilayered interconnect structures. FIG. 8, illustrates a non-limitative embodiment of a multilayered structure, where the structure of FIG. 7b is substantially repeated. FIG. 8 illustrates the use of hard mask 430 and hard mask 820 as etch stop/diffusion barriers for upper layers. It is readily recognizable that one may also create a multilayered structure by depositing amorphous carbon nitride as an etch stop/diffusion barrier for each layer, while choosing not to employ a hard mask. In addition, one may utilize an optional hard mask, like optional hard mask 430, and remove it during planarization.

Thus, as shown above, the use of amorphous carbon nitride as an etch stop diffusion barrier and/or a hard mask can reduce capacitance and RC delay, as well as provide mechanical strength for an interconnect structure. The foregoing description has been in reference to specific embodiments thereof. It will, however, be evident that various modifications and changes can be made thereto without departing from the broader spirit and scope of the invention as set forth in the appended claims. Therefore, the scope of the invention should be limited only by the appended claims.

What is claimed is:

1. A method of fabricating an interconnect structure in an integrated circuit comprising:
forming a first carbon nitride layer over an underlying layer;
depositing an interlayer dielectric on the first carbon nitride layer;
etching vias and trenches in the interlayer dielectric;
forming a barrier layer over the dielectric, so as to line the vias and the trenches;
forming a copper alloy over the barrier layer, so as to fill the vias and the trenches; and
planarizing the copper alloy.

2. The method of claim 1, further comprising:
forming a second layer of carbon nitride on the upper surface of the dielectric.

3. The method of claim 1, wherein the barrier layer includes tantalum or tantalum nitride.

4. The method of claim 1, wherein the interlayer dielectric is a polymer layer.

5. The method of claim 1, wherein the interlayer dielectric is a non-organic layer.

6. The method of claim 2, further comprising:
removing the second layer of carbon nitride.

7. The method of claim 1, wherein the planarizing comprises:
performing chemical mechanical polish (CMP).

8. The method of claim 1, wherein the method is repeated for multi-layered structures.

9. The method of claim 2, wherein the method is repeated for multi-layered structures.

10 The method of claim 6, wherein the method is repeated for multi-layered structures.

11. A method of fabricating an interconnect structure in an integrated circuit comprising:
forming an etch stop/diffusion barrier over an underlying layer;
depositing an interlayer dielectric on the etch stop/diffusion barrier;
forming a carbon nitride layer over the dielectric;
etching vias and trenches in the interlayer dielectric, using the carbon nitride layer as a hard mask;
forming a barrier layer over the hard mask and dielectric, so as to line the vias and trenches;
forming a copper alloy over the barrier layer, so as to fill the vias and the trenches; and
planarizing the copper alloy.

12. The method of claim 11, wherein the etch stop/diffusion barrier is silicon nitride.

13. The method of claim 11, wherein the interlayer dielectric is a polymer layer.

14. The method of claim 11, wherein the interlayer dielectric is a non-organic layer.

15. The method of claim 11, further comprising:
removing the carbon nitride hard mask.

16. The method of claim 1, wherein planarizing comprises:
performing chemical mechanical polish (CMP).

17. The method of claim 11, wherein the method is repeated for multi-layered structures.

18. The method of claim 15, wherein the method is repeated for multi-layered structures.

19. An interconnect structure comprising:
a first layer of carbon nitride disposed on an underlying layer;
vias and trenches defined by an interlayer dielectric disposed on the first layer of carbon nitride;
a barrier layer lining the vias and the trenches; and
a copper alloy over the barrier layer, filling the vias and the trenches.

20. The interconnect structure of claim 19, further comprising:
a second layer of carbon nitride disposed on the upper surface of the interlayer dielectric.

21. The interconnect structure of claim 19, wherein the barrier layer is tantalum or tantalum nitride.

22. The interconnect structure of claim 19, wherein the interlayer dielectric is a polymer layer.

23. The interconnect structure of claim 19, wherein the interlayer dielectric is a non-organic layer.

24. The interconnect structure of claim 19, wherein the structure is repeated for multilayered structures.

25. The interconnect structure of claim 20, wherein the structure is repeated for multilayered structures.

26. An interconnect structure comprising:
an etch stop/diffusion barrier disposed on an underlying layer;
vias and trenches defined by an interlayer dielectric disposed on the etch stop/diffusion barrier;
a carbon nitride hard mask disposed on the interlayer dielectric;
a barrier layer lining the vias and the trenches; and
a copper alloy over the barrier layer, filling the vias and the trenches.

27. The interconnect structure of claim 26, wherein the etch stop/diffusion barrier is silicon nitride.

28. The interconnect structure of claim 26, wherein the interlayer dielectric is a polymer layer.

29. The interconnect structure of claim 26, wherein the interlayer dielectric is a non-organic layer.

30. The interconnect structure of claim 26, whereby the structure is repeated for multilayered structures.
